(19) United States
(12) Patent Application Publication
(10) Pub. No.: US 2007/0269979 A1
(43) Pub. Date: Nov. 22, 2007

(54) Method of forming a pattern and method of manufacturing a semiconductor device using the same

(76) Inventor: Tai-Heui Cho, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/656,510

(22) Filed: Jan. 23, 2007

(30) Foreign Application Priority Data
May 19, 2006 (KR) 2006-45074

(51) Int. Cl. H01L 21/8242

(52) U.S. Cl. 438/669; 257/E21.657

(57) ABSTRACT

A method of forming a tungsten pattern includes forming a preliminary tungsten pattern on a substrate and partially removing a surface of the preliminary tungsten pattern using deionized water to form the tungsten pattern.

### BACKGROUND OF THE INVENTION

1. Field of the Invention

Embodiments of the present invention relate to a method of forming a pattern and a method of manufacturing a semiconductor device using the same. More particularly, embodiments of the present invention relate to a method of forming a tungsten pattern and a method of manufacturing a dynamic random access memory (DRAM) device having a tungsten bit line using the same.

2. Description of the Related Art

A DRAM device may include a storage capacitor and a transistor, with one of a source and a drain region, e.g., the drain region, of the transistor being electrically connected to the storage capacitor. The other of the source and drain region, e.g., the source region, may be electrically coupled to a bit line. The storage capacitor and the drain region of the transistor may be electrically connected to each other through a buried contact (BC). The bit line and the source region of the transistor may be electrically coupled to each other through a direct contact (DC).

As the level of integration of memory devices has been increased, a capacitor-on-bit line (COB) structure has been developed, wherein the DRAM device has a bit line positioned on a plane higher than that on which a capacitor is positioned. In the DRAM device having the COB structure, it may be necessary to increase the aspect ratio of the BC, i.e., the size of the BC may be reduced while the depth of the BC is increased, which may lead to difficulties in forming a BC hole using conventional photolithography.

In order to reduce or eliminate the difficulties presented by the high aspect ratio BC, a self-alignment contact formation method has been developed for forming the BC hole. The self-alignment contact formation method may make use of an etching selectivity between a spacer on a sidewall of the bit line and an insulation material between the bit lines. However, if the BC hole is misaligned or has a width greater than a predetermined width, an electrical short circuit may develop.

In particular, if the BC hole is misaligned or too wide, the spacer of the bit line may partially overlap the BC hole. In this case, despite the etching selectivity between the spacer and the insulation material, which may be, e.g., silicon oxide, the spacer may be over-etched when etching the insulation material to thereby partially expose the bit line. When the bit line is partially exposed by excessive etching, an electrical short between the BC and the bit line may be generated.

An electrical short between the BC and the bit line may also result from oxidation of tungsten used for the bit line. In particular, tungsten, having a resistance lower than that of polysilicon or tungsten silicide, may be a desirable material for the bit line. However, the tungsten may be oxidized at a high temperature, which may cause a dimension of the tungsten to increase. Therefore, when a spacer is formed on a sidewall of the bit line after forming the BC hole, an electrical short between the bit line and the BC may occur due to the growth of the tungsten.

In view of the above, an undercut tungsten bit line may be employed along with an oxide sidewall having a low dielectric constant. The undercut bit line may be formed using hydrogen peroxide. However, the hydrogen peroxide may cause a relatively violent oxidation reaction and, as a result, it may be difficult to reproducibly etch the bit line to a desired thickness. Thus, it may be difficult to form a bit line having a desired width when using hydrogen peroxide.

### SUMMARY OF THE INVENTION

The present invention is therefore directed to a method of forming a pattern and a method of manufacturing a semiconductor device using the same, which substantially overcome one or more of the problems due to the limitations and disadvantages of the related art.

It is therefore a feature of an embodiment of the present invention to provide a method of forming a tungsten pattern that includes removing a surface of the tungsten pattern using deionized water.

It is therefore another feature of an embodiment of the present invention to provide a method of forming a semiconductor device having a tungsten pattern that includes selectively removing a surface of the tungsten pattern.

At least one of the above and other features and advantages of the present invention may be realized by providing a method of forming a tungsten pattern including forming a preliminary tungsten pattern on a substrate and partially removing a surface of the preliminary tungsten pattern using deionized water to form the tungsten pattern.

Partially removing the surface of the preliminary tungsten pattern may be performed at a temperature of greater than or equal to about 80° C. Partially removing the surface of the preliminary tungsten pattern may be performed at a predetermined temperature and under pressure conditions that prevent the deionized water from boiling.

Partially removing the surface of the preliminary tungsten pattern may include heating the deionized water to a temperature of greater than or equal to about 80° C., and exposing the substrate to the heated deionized water. Partially removing the surface of the preliminary tungsten pattern may include heating the substrate to a temperature of greater than or equal to about 80° C. and dipping the heated substrate into the deionized water.

The surface of the preliminary tungsten pattern may be removed by the deionized water at a rate of about 0.5 Å/min. The substrate may include at least one other pattern, forming the tungsten pattern may include selectively removing a surface of the preliminary tungsten pattern using the deionized water without concomitant removal of a surface of the at least one other pattern, and the at least one other pattern may include at least one of titanium, titanium nitride, titanium silicide, and silicon oxide.

At least one of the above and other features and advantages of the present invention may also be realized by providing a method of reducing a dimension of a tungsten feature on a substrate, including providing the substrate having the tungsten feature formed thereon, wherein at least a portion of the tungsten feature is exposed, exposing the substrate to a reagent consisting essentially of deionized water, such that the deionized water is in contact with the exposed portion of the tungsten feature, and maintaining the contact between the deionized water and the exposed portion of the tungsten feature for a predetermined period of time, the predetermined period of time corresponding to a rate of removal of the tungsten feature by the deionized water.

The method may further include maintaining the substrate and the reagent at a predetermined temperature during the predetermined period of time, wherein the predetermined temperature is greater than or equal to about 80° C. The contact may be maintained until the deionized water reduces the dimension of the tungsten feature by a predetermined amount.

At least one of the above and other features and advantages of the present invention may further be realized by providing a method of manufacturing a semiconductor device, including forming an insulation layer on a substrate having a contact formation region, sequentially forming a tungsten layer and a hard mask layer on the insulation interlayer, patterning the hard mask layer and the tungsten layer to form a preliminary bit line structure, the preliminary bit line structure including a stack of a preliminary tungsten pattern and a hard mask pattern, and selectively removing a surface of the preliminary tungsten pattern using deionized water to form a bit line structure, the bit line structure including a tungsten pattern and the hard mask pattern.

Selectively removing the surface of the preliminary tungsten pattern may reduce a width of the preliminary tungsten pattern to be less than a corresponding width of the hard mask pattern. The method may further include forming a spacer on a sidewall of the bit line structure, covering the bit line structure with a second insulation layer, partially etching the second insulation layer adjacent to the bit line structure so as to form a contact hole, the contact hole exposing the contact formation region and having a sidewall at least partially defined by the spacer, and filling the contact hole with a conductive material.

Selectively removing the surface of the preliminary tungsten pattern may be performed at a temperature of greater than or equal to about 80° C. Partially removing the surface of the preliminary tungsten pattern may be performed at a predetermined temperature and under pressure conditions that prevent the deionized water from boiling.

Partially removing the surface of the preliminary tungsten pattern may include heating the deionized water to a temperature of greater than or equal to about 80° C. and exposing the substrate to the heated deionized water. Partially removing the surface of the preliminary tungsten pattern may include heating the substrate to a temperature of greater than or equal to about 80° C. and dipping the heated substrate into the deionized water.

The method may further include forming a barrier metal layer before forming the tungsten layer, wherein selectively removing a surface of the preliminary tungsten pattern leaves the barrier metal layer substantially unchanged. The barrier metal layer may include at least one of titanium nitride and titanium. A width of the tungsten pattern may be about 50% to about 95% of a corresponding width of the preliminary tungsten pattern.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1 and 2 illustrate cross-sectional views of stages in a method of forming a tungsten pattern in accordance with an exemplary embodiment of the present invention;

FIGS. 3 to 10 illustrate cross-sectional views of stages in a method of manufacturing a semiconductor device in accordance with a second exemplary embodiment of the present invention;

FIG. 11 illustrates a scanning electron microscopic analysis of a pattern formed according Example 1 of the present invention; and

FIG. 12 illustrates a scanning electron microscopic analysis of a pattern formed according to Comparative Example 1.

### DETAILED DESCRIPTION OF THE INVENTION

Korean Patent Application No. 200645074 filed on May 19, 2006, in the Korean Intellectual Property Office, and entitled: “Method of Forming a Pattern and Method of Manufacturing a Semiconductor Device Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

It will be understood that when an element or layer is referred to as being “connected to” or “coupled to” another element or layer, it can be directly connected or coupled to the other element or layer or intervening elements or layers may be present. In contrast, when an element is referred to as being “directly on,” “directly connected to” or “directly coupled to” another element or layer, there are no intervening elements or layers present. To the extent used herein, the term “and/or” includes any and all combinations of one or more of the associated listed items.

It will be understood that, although the terms “first,” “second,” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the figures, the dimensions of layers and regions may be exaggerated for clarity of illustration. Like reference numerals refer to like elements throughout.

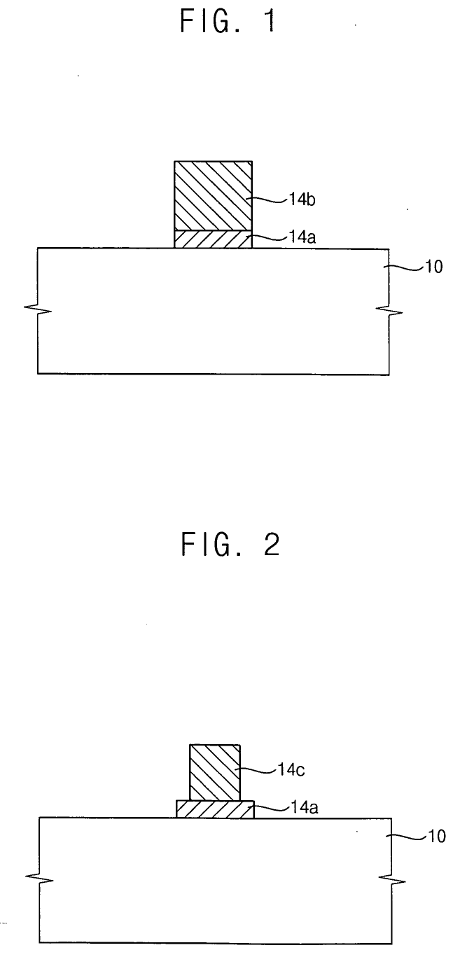

FIGS. 1 and 2 illustrate cross-sectional views of stages in a method of forming a tungsten pattern in accordance with an exemplary embodiment of the present invention. Referring to FIG. 1, a semiconductor substrate 10 may have a barrier metal pattern 14a and a preliminary tungsten pattern 14b sequentially stacked thereon. The barrier metal pattern 14a and the preliminary tungsten pattern 14b may have substantially the same widths.

This structure may be formed by forming a barrier metal layer, e.g., one or more of a titanium layer, a titanium nitride layer, etc., (not shown) on the substrate 10. A tungsten layer (not shown) may be formed on the barrier metal layer, e.g., by a chemical vapor deposition (CVD) method that uses a reaction gases such as WF₆ gas and H₂ or SiH₄, by an atomic layer deposition (ALD) method using gases such as WF₆, a purge gas, and H₂ or SiH₄ gas, wherein the reaction gases and the purge gas are alternately supplied to the barrier metal layer, etc. A mask pattern (not shown) may be formed on the tungsten layer. The mask pattern may include one or more of a photoresist pattern, a hard mask pattern, etc.

The tungsten and barrier metal layers may be etched, e.g., with an anisotropic etch while using the hard mask pattern as an etch mask, to define the barrier metal pattern 14a and the preliminary tungsten pattern 14b. The anisotropic etching method may include, e.g., a plasma dry etching method using SF₆ gas as an etching gas and a pressure control gas and/or carrier gas such as N₂. The etching gas may additionally include, e.g., HBr gas. The anisotropic etching may yield the structure including the barrier metal pattern 14a and the preliminary tungsten pattern 14b sequentially stacked, wherein the barrier metal pattern 14a and the preliminary tungsten pattern 14b have substantially the same widths.

FIG. 2 illustrates the substrate 10 having the barrier metal pattern 14a and a tungsten pattern 14c sequentially stacked thereon. This structure may be formed by partially removing a surface of the preliminary tungsten pattern 14b using deionized water. Partially removing the surface of the preliminary tungsten pattern 14b may yield the tungsten pattern 14c having a width less than that of the preliminary tungsten pattern 14b. That is, one or more side surfaces of the preliminary tungsten pattern may be removed through reaction with the deionized water.

The substrate 10 including the barrier metal pattern 14a and the preliminary tungsten pattern 14b may be dipped into deionized water so that the deionized water partially removes the tungsten to form the tungsten pattern 14c having a width less than that of the preliminary tungsten pattern 14b. The deionized water may selectively remove the surface of the preliminary tungsten pattern 14b relative to other features, e.g., the barrier metal pattern 14a, such that the width of the tungsten pattern 14c is less than that of the barrier metal pattern 14a.

Details of the removal of the surface of the preliminary tungsten pattern 14b using the deionized water will now be provided, although to the extent that theoretical processes are discussed, it will be understood that the present invention is not limited to a particular mechanism. During exposure of the preliminary tungsten pattern 14b to the deionized water, an oxidation reaction may occur at the surface of the preliminary tungsten pattern 14b where tungsten in the preliminary tungsten pattern 14b and the deionized water make contact, thereby forming a tungsten oxide layer. The deionized water may remove the tungsten oxide layer, and the underlying surface of the preliminary tungsten pattern 14b exposed by the removal of the tungsten oxide layer may then be oxidized. The oxidized surface of the preliminary tungsten pattern 14b may then be removed using the deionized water as the just-described processes are repeated.

To facilitate the removal of the surface of the tungsten by the deionized water, a temperature of the deionized water and/or the substrate 10 may be increased. The increased temperature may facilitate the oxidation process. The use of a temperature of below about 80° C. may result in the oxidation reaction between the tungsten and the deionized water becoming slower. The use of a temperature of greater than about 100° C. may cause the deionized water to evaporate and/or not be maintained in a liquid state. Therefore, the temperature of the deionized water and/or the substrate may be greater than or equal to about 80° C. The temperature of the deionized water and/or the substrate may be less than or equal to about 100° C., e.g., about 95° C. A temperature of about 95° C. may remove the preliminary tungsten pattern 14b at a rate of about 0.5 Å/min. Of course, it will be appreciated that higher temperatures may be employed if adequate control over the temperature and pressure conditions are provided, such that the deionized water may be prevented from boiling or evaporating, i.e., maintained in a liquid state.

The deionized water may be heated, and the substrate 10 may be exposed thereto, e.g., by dipping the substrate 10 into the heated deionized water. In another implementation, the deionized water may have a temperature of about room temperature, and the substrate 10 may have a higher temperature, e.g., about 80° C. to about 100° C., and the substrate 10 may be dipped into the room temperature deionized water.

The deionized water may reduce a width of the preliminary tungsten pattern 14b. The substrate 10 may include at least one other pattern, and reducing a width of the preliminary tungsten pattern 14b may selectively remove a surface of the preliminary tungsten pattern 14b using the deionized water without concomitant removal of a surface of the at least one other pattern. For example, the deionized water may not remove the barrier metal pattern 14a, which may be, e.g., titanium or the titanium nitride. Thus, the width of the barrier metal pattern 14a may be unchanged after forming the tungsten pattern 14c.

According to this exemplary embodiment, a preliminary tungsten pattern may be formed using, e.g., dry etching, and a tungsten pattern having a width less than that of the preliminary tungsten pattern may be formed by reducing a width of the preliminary tungsten pattern using deionized water. Although the surface of the tungsten pattern may be removed by processing with the deionized water, it may remain otherwise undamaged by the processing.

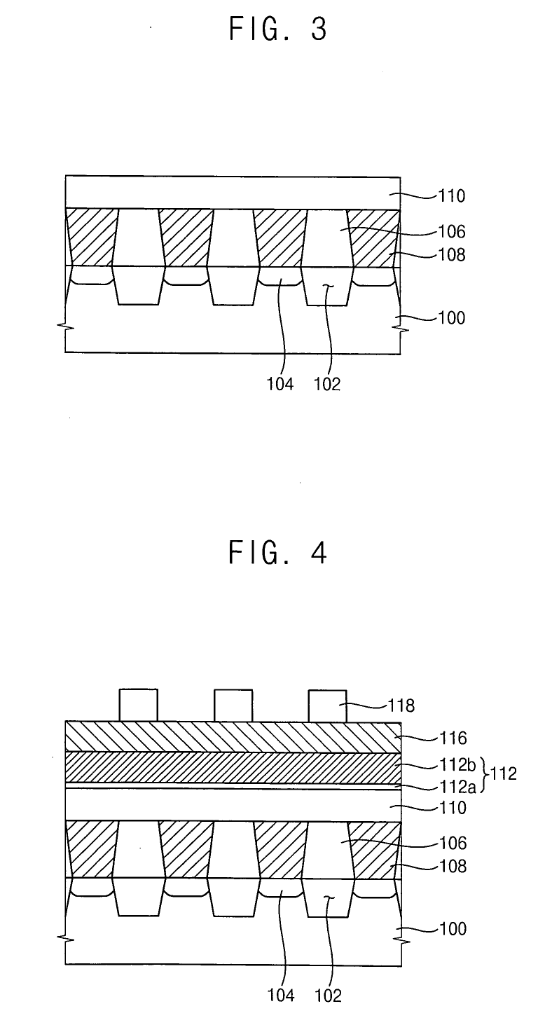

FIGS. 3 to 10 illustrate cross-sectional views of stages in a method of manufacturing a semiconductor device in accordance with a second exemplary embodiment of the present invention. The cross-sectional views are taken along a direction substantially parallel with a lengthwise direction of a gate electrode (not shown).

Referring to FIG. 10, the semiconductor device may include a substrate 100, e.g., a semiconductor substrate, one or more isolation layers 102 defining one or more active regions, and source/drain regions 104. The substrate 100 may further include a first insulation interlayer 106 and one or more contact plugs 108, and a second insulation interlayer 110. A bit line structure 117 on the substrate 100 may include a barrier metal pattern 114a, a tungsten pattern 114c, and a second hard mask pattern 116a. A first spacer 120 may be disposed on a sidewall of the bit line structure 117. The substrate 100 may also include a third insulation interlayer 122, a second spacer 126 and a storage node contact 130.

Referring now to FIG. 3, a shallow trench isolation (STI) method may be performed on the substrate 100 to define an active region and an isolation region of the substrate 100. Trenches may be formed at a surface portion of the isolation region and may be filled with the isolation layers 102. The active regions may be islands that extend in a first direction corresponding to a lengthwise direction of the active region. Two DRAM devices may be formed in each of the active regions.

A gate electrode structure (not shown), which may act as a word line, may be formed on the substrate 100. In particular, a gate oxide layer may be formed on the active region of the substrate 100. A first conductive layer, serving as the gate electrode, and a first hard mask layer may be sequentially formed on the substrate 100 having the gate oxide layer. The first conductive layer may include, e.g., a polysilicon layer doped with impurities and a tungsten silicide layer stacked on the polysilicon layer. In another implementation, the first conductive layer may include a polysilicon layer doped with impurities and a tungsten layer stacked on the polysilicon layer. The first hard mask layer may be patterned by a photolithography method to form a first hard mask pattern. The first conductive layer may be etched using the first hard mask pattern as an etching mask to form the gate electrode. The gate electrode may have a linear shape extending along a second direction substantially perpendicular to the first direction. A silicon nitride layer may be formed on the gate electrode, the first hard mask pattern and the substrate 100. The silicon nitride layer may be anisotropically etched to form a gate spacer. Impurities may be implanted into the substrate 100 at both sides of the gate electrode to form source/drain regions 104, to form a MOS transistor of the DRAM device.

Referring again to FIG. 3, the first insulation interlayer 106 may entirely cover the first hard mask pattern. The first insulation interlayer 106 may include a silicon oxide layer and may be formed by, e.g., a CVD method, a plasma enhanced chemical vapor deposition (PECVD) method, a high density chemical vapor deposition (HDCVD) method, etc. Examples of the first insulation interlayer 106 may include BPSG, PSG, SOG, PE-TEOS, USG, etc. A chemical mechanical polishing (CMP) method may be performed on the first insulation interlayer 106 to planarize a surface of the first insulation interlayer 106.

A photoresist pattern (not shown) may be formed on the first insulation interlayer 106. The first insulation interlayer 106 may be etched using the photoresist pattern as an etching mask to form a first contact hole that exposes an upper surface of the source/drain region 104. The first contact hole may be formed by a self-alignment method using an etching selectivity between the gate spacer (not shown) and the first insulation interlayer 106. The photoresist pattern may be then removed, e.g., using one or more of an ashing method, a stripping method, etc.

A second conductive layer (not shown) may be formed on the first insulation interlayer 106 to fill up the first contact hole. The second conductive layer may include, e.g., a doped polysilicon layer. The second conductive layer may be partially removed, e.g., using a CMP method, until an upper face of the first insulation interlayer 106 is exposed, so as to form the contact plug 108 in the first contact hole. The contact plug 108 may be electrically connected to the source/drain region 104 of the MOS transistor.

As illustrated in FIG. 3, the contact plug 108 may be electrically connected to a drain region of the MOS transistor. The contact plug 108 may also be electrically connected to a capacitor as described below. Similarly, although not illustrated, a second contact plug may electrically connect a source region of the MOS transistor to a bit line.

A second insulation interlayer 110 may be formed on the contact plug 108 and the first insulation interlayer 106. The second insulation interlayer 110 may include, e.g., a silicon oxide layer. A photoresist pattern (not shown) may be formed on the second insulation interlayer 110. The second insulation interlayer 110 may be etched using the photoresist pattern as an etching mask to form a second contact hole for the second contact plug (not shown), the second contact hole exposing an upper surface of the contact plug electrically connected to the bit line.

Referring to FIG. 4, a third conductive layer 112 for the bit line may be formed on the second insulation interlayer 110 to fill up the second contact hole and to form the second contact plug. The third conductive layer 112 may include, e.g., a titanium/titanium nitride layer 112a and a tungsten layer 112b on the titanium/titanium nitride layer 112a.

The titanium/titanium nitride layer 112a may serve as a barrier metal layer for preventing diffusion of metal atoms in the tungsten layer 112b. The titanium/titanium nitride layer 112a may serve as the second contact plug and an ohmic contact. Titanium in the titanium/titanium nitride layer 112a may react with polysilicon in the underlying contact plug to form a titanium silicide layer as the ohmic layer at an interface between the titanium/titanium nitride layer 112a and the underlying contact plug.

A second hard mask layer 116 may be formed on the tungsten layer 112b. The second hard mask layer 116 may include, e.g., a silicon nitride layer. A photoresist pattern 118 may be formed on the second hard mask layer 116 and may function as a mask pattern for patterning the third conductive layer 112 for the bit line.

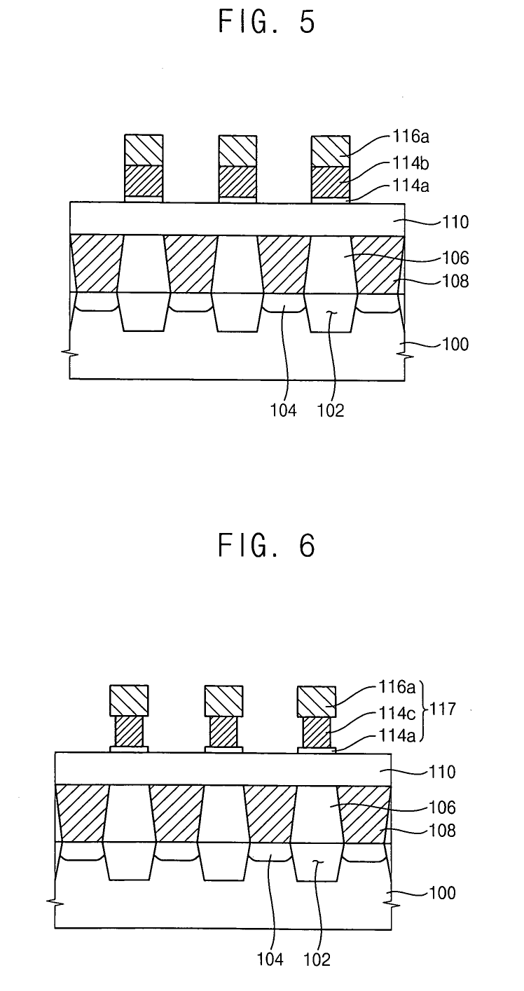

Referring to FIG. 5, the second hard mask layer 116 may be etched using the photoresist pattern 118 as an etching mask to form a second hard mask pattern 116a. The photoresist pattern 118 may then be removed, e.g., using one or more of an ashing method, a stripping method, etc. The third conductive layer 112 may be anisotropically etched, e.g., by a dry etching method, using the second hard mask pattern 116a as an etching mask to form a preliminary tungsten pattern 114b, the barrier metal pattern 114a, and a bit line contact (not shown) electrically connected to the barrier metal pattern 114a.

The preliminary tungsten pattern 114b may have a linear shape that extends along a direction substantially perpendicular to the lengthwise direction of the gate electrode (not shown). The barrier metal layer pattern 114a and the preliminary tungsten pattern 114b may serve as the bit line, as described in greater detail below.

Referring to FIG. 6, deionized water may be used to selectively remove a surface of the preliminary tungsten pattern 114b to form the tungsten pattern 114c. The tungsten pattern 114c may have a width less than that of the preliminary tungsten pattern 114b, less than that of the barrier metal pattern 114a, and less than that of the second hard mask pattern 116a. The surface of the preliminary tungsten pattern 114b may be selectively removed using deionized water, as described above.

For example, the substrate 100 having the preliminary tungsten pattern 114b thereon may be dipped into the deionized water, and one or both of the substrate 100 and the deionized water may be heated. Of course, any of the implementations of the above-described embodiment may be employed according to the particular requirements of the manufacturing environment. As a result of selectively removing the surface of the preliminary tungsten pattern 114b using the deionized water, the substrate 100 may include the bit line structure 117 having the barrier metal layer pattern 114a, the tungsten pattern 114c, and the second hard mask pattern 116a stacked on the substrate 100 in sequence.

The width of the tungsten pattern 114c may be about 50% to about 95% that of the second hard mask pattern 116a. For example, in an implementation, the width of the second hard mask pattern 116a may be about 70 nm and the width of the tungsten pattern 114c may be about 50 nm to about 60 nm. If the width of the preliminary tungsten pattern 114b is reduced to a large degree, e.g., so that the width of the tungsten pattern 114c is less than about 50% that of the second hard mask pattern 116a, the bit line structure 117 may become unstable and may collapse. If the width of the preliminary tungsten pattern 114b is only slightly reduced, e.g., so that the width of the tungsten pattern 114c is greater than about 95% that of the second hard mask pattern 116a, the tungsten in the tungsten pattern 114c may grow abnormally.

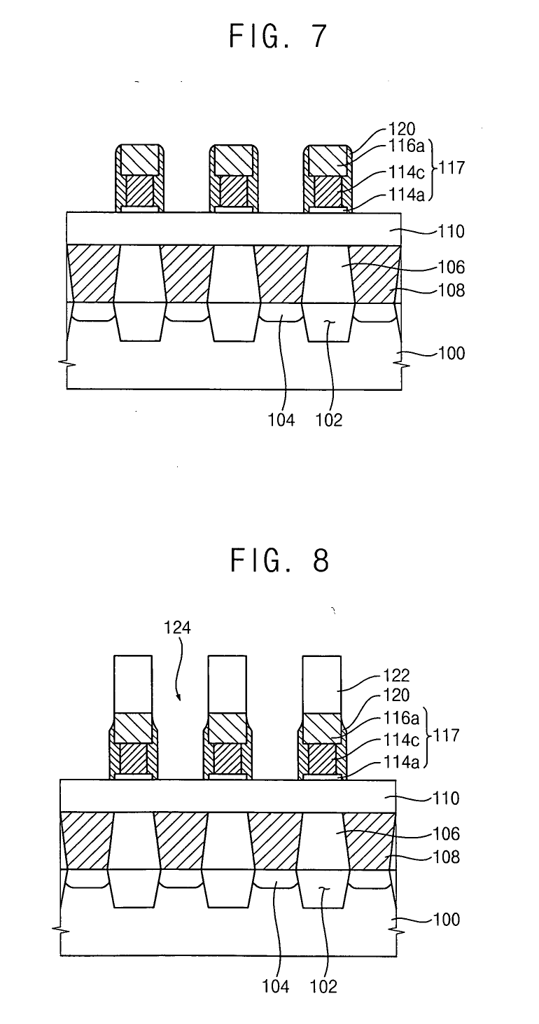

Referring to FIG. 7, a nitride layer (not shown) may be formed on the bit line structure 117 and the second insulation interlayer 110. The nitride layer may then be anisotropically etched to form the first spacer 120 on a sidewall of the bit line structure 117. Since the width of the tungsten pattern 114c may be narrower than that of the second hard mask pattern 116a, a middle portion of the first spacer 120 on the sidewall of the tungsten pattern 114c may have a thickness greater than that of the remaining portions of the first spacer 120. That is, the tungsten pattern 114c may correspond to an undercut of the bit line structure 117 so that the middle portion of the first spacer 120 has a thickness greater than that of the remaining portions of the first spacer 120. The middle portion of the first spacer 120 may not be etched by the anisotropic etching method.

Referring to FIG. 8, a third insulation interlayer 122 may be formed on the bit line structure 117. In detail, a photoresist pattern (not shown) may be formed on a third insulation material layer (not shown), the photoresist pattern having a linear shape extending in a direction substantially perpendicular to the extending direction of the bit line structure 117. The third insulation material layer, the second insulation interlayer 120 and part of the first spacer 120 may be etched using the photoresist pattern as an etching mask to form a third contact hole 124 adjacent to the third insulation interlayer 122, with the third contact hole 124 exposing an upper surface of the contact plug 108. The third insulation interlayer 122 may include, e.g., a silicon oxide layer.

The third contact hole 124 may be self-aligned to the first spacer 120 using an etching selectivity between the middle portion of the first spacer 120 on the sidewall of the bit line structure 117 and the third insulation interlayer 122. Thus, the first spacer 120 may be partially removed due to the etching selectivity in the etching method for forming the third contact hole 124. However, since the middle portion of the first spacer 120 on the sidewall of the tungsten pattern 114c has a thickness greater than that of the remaining portions of the first spacer 120, the tungsten pattern 114c may not be exposed even if some of the middle portion of the first spacer 120 is removed.

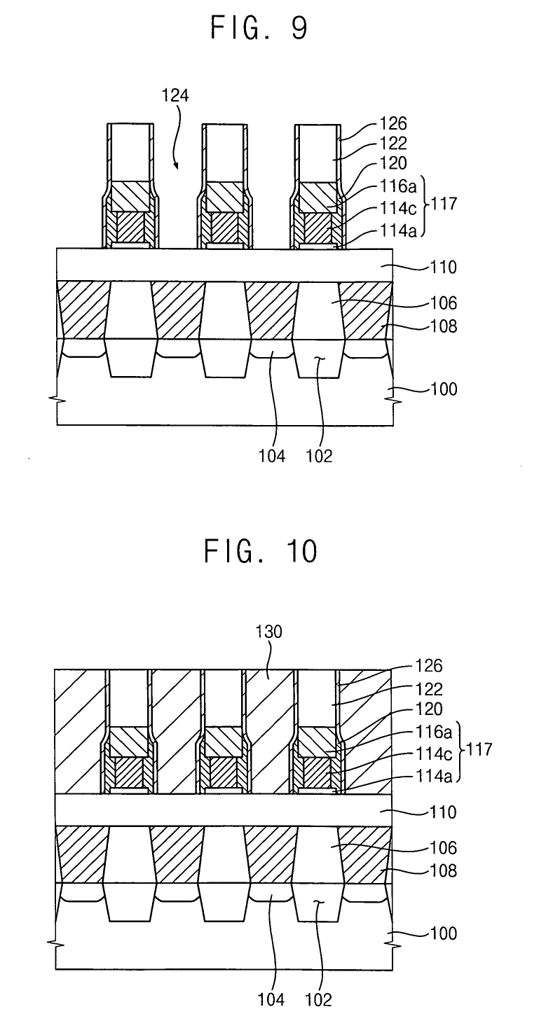

Referring to FIG. 9, a silicon nitride layer (not shown) may be formed on the third insulation interlayer 122, e.g., to fill up the third contact hole 124. The silicon nitride layer may be anisotropically etched to form a second spacer 126 on a sidewall of the third contact hole 124. The second spacer 126 may help reduce or prevent a short between the tungsten pattern 114c and a storage node contact that is subsequently formed.

Conventionally, if a spacer on the sidewall of the tungsten pattern is thin or is partially removed, the surface of the tungsten pattern may grow abnormally during the formation of a silicon nitride layer on the sidewall of the tungsten pattern. That is, the tungsten pattern may be oxidized and expand at a high temperature, so that tungsten whiskers may be generated at the thin portion of the first spacer. In contrast, according to this embodiment of the present invention, the width of the tungsten pattern 114c may be narrowed, e.g., to less than that of the second hard mask pattern 116c. Therefore, the middle portion of the first spacer 120 may have a greater thickness than that of the remaining portions of the first spacer 120, and, as a result, the surface of the tungsten pattern 114c may not be exposed during etching. Further, the middle portion of the first spacer 120 on the sidewall of the tungsten pattern 114c may suppress abnormal growth of the tungsten pattern 114c.

Referring to FIG. 10, a fourth conductive layer (not shown) may be formed on the third insulation interlayer 122 to fill up the third contact hole 124. The fourth conductive layer may include, e.g., a doped polysilicon layer. The fourth conductive layer may be partially removed, e.g., by a CMP method, until an upper surface of the third insulation interlayer 122 is exposed to form a storage node contact 130. A storage node, e.g., a cylindrical capacitor (not shown), may be formed on the storage node contact 130 to form the DRAM device.

According to this example embodiment, the tungsten pattern 114c may serve as the undercut portion of the bit line structure 117. Thus, the middle portion of the first spacer 120 on the sidewall of the tungsten pattern 114c may have a thickness greater than other portions of the first spacer 120, so that the tungsten pattern 114c may not grow abnormally while forming the second spacer 126. As a result, a short between the tungsten pattern 114c and the storage node contact 130 may be suppressed.

Forming Tungsten Patterns: Example 1, a Tungsten Pattern in Accordance with the Present Invention

A barrier metal layer including titanium nitride was formed on a semiconductor substrate. A tungsten layer was then formed on the barrier metal layer. A hard mask layer including silicon nitride was formed on the tungsten layer. The hard mask layer was patterned to form a hard mask pattern. The tungsten layer and the barrier metal layer were anisotropically etched using the hard mask pattern as an etching mask to form a tungsten pattern and a barrier metal layer pattern. The substrate was then processed by dipping into deionized water having a temperature of 95° C. for 2 hours.

Tungsten Pattern in Accordance with Comparative Example 1

A barrier metal layer including titanium nitride was formed on a semiconductor substrate. A tungsten layer was then formed on the barrier metal layer. A hard mask layer including silicon nitride was formed on the tungsten layer. The hard mask layer was patterned to form a hard mask pattern. The tungsten layer and the barrier metal layer were anisotropically etched using the hard mask pattern as an etching mask to form a tungsten pattern and a barrier metal layer pattern.

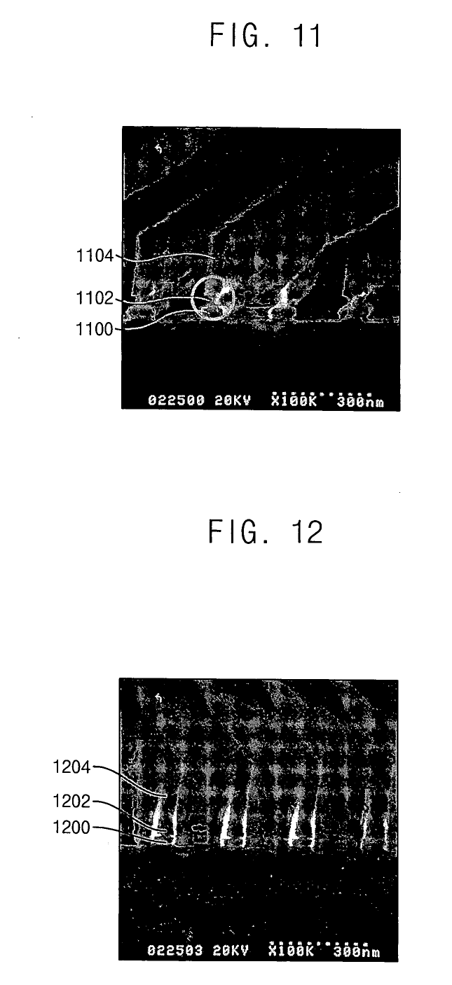

FIG. 11 illustrates a scanning electron microscopic analysis of a pattern formed according to Example 1 of the present invention, and FIG. 12 illustrates a scanning electron microscopic analysis of a pattern formed according to Comparative Example 1.

Referring to FIG. 11, the tungsten pattern 1102 of Example 1 is almost removed after the substrate is dipped into deionized water having a temperature of 95° C. for 2 hours. Further, although the hard mask pattern 1104 and the barrier metal layer pattern 1100 were likewise dipped into the deionized water, the hard mask pattern 1104 and the barrier metal layer pattern 100 remain essentially intact. Accordingly, it is evident that the surface of the tungsten pattern 1102 was selectively removed.

In contrast, referring to FIG. 12, it can be noted in Comparative Example 1 that the tungsten pattern 1202 and the barrier metal layer pattern 1200 have widths substantially the same as that of the hard mask pattern 1204.

Measuring Thicknesses of Layers in Patterns: Example 2, a Tungsten Layer in Accordance with the Present Invention

A barrier metal layer including titanium nitride was formed on a semiconductor substrate. A tungsten layer was then formed on the barrier metal layer. A hard mask layer including silicon nitride was formed on the tungsten layer. The tungsten layer had a thickness of 1121 Å. The substrate was then processed by dipping into deionized water having a temperature of 95° C. for 2 hours.

Tungsten Silicide Layer in Accordance with Comparative Example 2

A tungsten silicide layer was formed on a semiconductor substrate by a CVD method using a reaction gas including a dichlorosilane (SiH₂Cl₂) gas and a WF₆ gas. The tungsten silicide layer had a thickness of 1416 Å. The substrate was then processed by dipping into deionized water having a temperature of 95° C. for 2 hours.

Silicon Oxide Layer in Accordance with Comparative Example 3

A silicon oxide layer was formed on a semiconductor substrate by a HDCVD method. The silicon oxide layer had a thickness of 1007 Å. The substrate was then processed by dipping into deionized water having a temperature of 95° C. for 2 hours.

Thicknesses of the layers of Example 2 and Comparative Examples 2 and 3 were measured. The measured thicknesses are reproduced in the following Table 1.

TABLE 1

| | | Comparative | Comparative |
|---|---|---|---|
| | Example 2 | Example 2 | Example 3 |
| | (tungsten) | (tungsten silicide) | (silicon oxide) |
| Initial thickness | 1121 Å | 1007 Å | 1416 Å |
| Processed | 1059 Å | 1007 Å | 1416 Å |
| thickness | | | |
| Change in | 62 Å | 0 Å | 0 Å |
| thickness | | | |

Referring to Table 1, it is apparent that the deionized water removed the tungsten layer at a rate of about 0.5 Å/min, while the deionized water did not remove either the tungsten silicide layer or the silicon oxide layer. Therefore, it is apparent that the deionized water selectively removed the tungsten layer.

According to embodiments of the present invention, a tungsten layer may be selectively removed without damaging layers adjacent to the tungsten layer. Thus, a short between the tungsten pattern and a contact disposed adjacent to the tungsten pattern may be suppressed. As a result, process errors in manufacturing a semiconductor device may be significantly reduced and yields of the semiconductor device may be increased.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a tungsten pattern, comprising:
forming a preliminary tungsten pattern on a substrate; and
partially removing a surface of the preliminary tungsten pattern using deionized water to form the tungsten pattern.

2. The method as claimed in claim 1, wherein partially removing the surface of the preliminary tungsten pattern is performed at a temperature of greater than or equal to about 80° C.

3. The method as claimed in claim 2, wherein partially removing the surface of the preliminary tungsten pattern is performed at a predetermined temperature and under pressure conditions that prevent the deionized water from boiling.

4. The method as claimed in claim 1, wherein partially removing the surface of the preliminary tungsten pattern comprises heating the deionized water to a temperature of greater than or equal to about 80° C.; and
exposing the substrate to the heated deionized water.

5. The method as claimed in claim 1, wherein partially removing the surface of the preliminary tungsten pattern comprises heating the substrate to a temperature of greater than or equal to about 80° C.; and
dipping the heated substrate into the deionized water.

6. The method as claimed in claim 1, wherein the surface of the preliminary tungsten pattern is removed by the deionized water at a rate of about 0.5 Å/min.

7. The method as claimed in claim 1, wherein the substrate includes at least one other pattern,
forming the tungsten pattern includes selectively removing a surface of the preliminary tungsten pattern using the deionized water without concomitant removal of a surface of the at least one other pattern, and
the at least one other pattern includes at least one of titanium, titanium nitride, titanium silicide, and silicon oxide.

8. A method of reducing a dimension of a tungsten feature on a substrate, comprising:
providing the substrate having the tungsten feature formed thereon, wherein at least a portion of the tungsten feature is exposed;
exposing the substrate to a reagent consisting essentially of deionized water, such that the deionized water is in contact with the exposed portion of the tungsten feature; and
maintaining the contact between the deionized water and the exposed portion of the tungsten feature for a predetermined period of time, the predetermined period of time corresponding to a rate of removal of the tungsten feature by the deionized water.

9. The method as claimed in claim 8, further comprising maintaining the substrate and the reagent at a predetermined temperature during the predetermined period of time, wherein the predetermined temperature is greater than or equal to about 80° C.

10. The method as claimed in claim 8, wherein the contact is maintained until the deionized water reduces the dimension of the tungsten feature by a predetermined amount.

11. A method of manufacturing a semiconductor device, comprising:
forming an insulation layer on a substrate having a contact formation region;
sequentially forming a tungsten layer and a hard mask layer on the insulation interlayer;
patterning the hard mask layer and the tungsten layer to form a preliminary bit line structure, the preliminary bit line structure including a stack of a preliminary tungsten pattern and a hard mask pattern; and
selectively removing a surface of the preliminary tungsten pattern using deionized water to form a bit line structure, the bit line structure including a tungsten pattern and the hard mask pattern.

12. The method as claimed in claim 11, wherein selectively removing the surface of the preliminary tungsten pattern reduces a width of the preliminary tungsten pattern to be less than a corresponding width of the hard mask pattern.

13. The method as claimed in claim 11, further comprising:
forming a spacer on a sidewall of the bit line structure;
covering the bit line structure with a second insulation layer;
partially etching the second insulation layer adjacent to the bit line structure so as to form a contact hole, the contact hole exposing the contact formation region and having a sidewall at least partially defined by the spacer; and
filling the contact hole with a conductive material.

14. The method as claimed in claim 11, wherein selectively removing the surface of the preliminary tungsten pattern is performed at a temperature of greater than or equal to about 80° C.

15. The method as claimed in claim 14, wherein partially removing the surface of the preliminary tungsten pattern is performed at a predetermined temperature and under pressure conditions that prevent the deionized water from boiling.

16. The method as claimed in claim 11, wherein partially removing the surface of the preliminary tungsten pattern comprises heating the deionized water to a temperature of greater than or equal to about 80° C.; and
exposing the substrate to the heated deionized water.

17. The method as claimed in claim 11, wherein partially removing the surface of the preliminary tungsten pattern comprises heating the substrate to a temperature of greater than or equal to about 80° C.; and
dipping the heated substrate into the deionized water.

18. The method as claimed in claim 11, further comprising forming a barrier metal layer before forming the tungsten layer, wherein selectively removing a surface of the preliminary tungsten pattern leaves the barrier metal layer substantially unchanged.

19. The method as claimed in claim 18, wherein the barrier metal layer includes at least one of titanium nitride and titanium.

20. The method as claimed in claim 11, wherein a width of the tungsten pattern is about 50% to about 95% of a corresponding width of the preliminary tungsten pattern.
